(19) United States
(12) Patent Application Publication
(10) Pub. No.: US 2012/0241882 A1
(43) Pub. Date: Sep. 27, 2012

(54) SEMICONDUCTOR MEMORY DEVICE AND METHOD FOR FABRICATING THE SAME

(76) Inventor: Joo Young MOON, Yongin-si (KR)

(21) Appl. No.: 13/336,478

(22) Filed: Dec. 23, 2011

(30) Foreign Application Priority Data
Mar. 23, 2011 (KR) 10-2011-0025979

(51) Int. Cl. H01L 29/82; H01L 21/02

(52) U.S. Cl. 257/421; 438/3; 257/E21.002; 257/E29.323

(57) ABSTRACT

A method for fabricating a semiconductor device, the method comprising forming a magnetic tunnel junction pattern on a substrate, forming a spacer having a metal oxide layer on a sidewall of the magnetic tunnel junction pattern, forming a first interlayer insulating layer on the substrate having the spacer and the magnetic tunnel junction pattern formed thereon, forming a first damascene pattern by etching the first interlayer insulating layer so that a top portion of the magnetic tunnel junction pattern is exposed, and forming a first wire buried in the first damascene pattern.

### CROSS-REFERENCE TO RELATED APPLICATIONS

The present application claims priority of Korean Patent Application No. 10-2011-0025979, filed on Mar. 23, 2011, which is incorporated herein by reference in its entirety.

### BACKGROUND

1. Field

Exemplary embodiments of the present invention relate to a method for fabricating a semiconductor device.

2. Description of the Related Art

A dynamic random access memory (DRAM) and a flash memory are examples of semiconductor devices. The DRAM has a fast data processing speed because of free data access, and the flash memory is capable of storing nonvolatile data. Conversely, the DRAM periodically refreshes data, and the flash memory has a slower data processing speed because of difficult data access.

In semiconductor device industries, semiconductor devices having advantages of the DRAM and the flash memory may be useful to produce. As a result, a resistance-variation random access memory has been developed. The resistance-variation random access memory is a semiconductor device that stores data by varying the resistance of a resistor and accesses data through a transistor. The resistance-variation random access memory has the free data access feature of the DRAM and the non-volatile data storage feature of the flash memory.

A spin transfer torque RAM (STTRAM) and a resistive RAM (ReRAM) are examples of the resistance-variation random access memory. The STTRAM includes a magnetic tunnel junction to store data. The magnetoresistance (MR) of the magnetic tunnel junction changes depending on magnetization directions of two magnetic layers. The resistance-variation random access memory reads whether data stored in the magnetic tunnel junction is logical 1 or 0 by sensing a change in MR. The ReRAM is a semiconductor device that stores data by varying the resistance of a magnetic tunnel junction according to a current supplied to the magnetic tunnel junction, and the ReRAM uses a thin film such as NiO, TiO, or HfO as the magnetic tunnel junction.

Additionally, the magnetic tunnel junction is connected to a metal wire to receive a current supplied through the metal wire. To this end, the magnetic tunnel junction is exposed by performing a damascene process, and a metal layer is then buried in the magnetic tunnel junction so that the metal wire is electrically connected to the magnetic tunnel junction. However, the magnetic tunnel junction may be exposed in the damascene process. Therefore, the magnetic tunnel junction may be damaged.

### SUMMARY

An embodiment of the present invention is directed to a semiconductor device and a method for fabricating the semiconductor device that prevents a magnetic tunnel junction from being damaged in a damascene process.

In accordance with an embodiment of the present invention, a method for fabricating a semiconductor device includes forming a magnetic tunnel junction pattern on a substrate; forming a spacer having a metal oxide layer on a sidewall of the magnetic tunnel junction pattern; forming a first interlayer insulating layer on the substrate having the spacer and the magnetic tunnel junction pattern formed thereon; forming a first damascene pattern by etching the first interlayer insulating layer so that a top portion of the magnetic tunnel junction pattern is exposed; and forming a first wire buried in the first damascene pattern.

In the semiconductor device of the present invention, a spacer is disposed on a side of a magnetic tunnel junction pattern to prevent a magnetic tunnel junction from being damaged when performing a damascene process. Particularly, if the spacer is formed with a metal oxide layer and an interlayer insulating layer is etched using at least one gas of CF₄, CHF₃, CH₃F and C₄F₆, the spacer is not etched. Thus, the magnetic tunnel junction may not be damaged.

In accordance with another embodiment of the present invention, a method for fabricating a semiconductor device, the method comprising forming a first insulating layer on a substrate; forming a first contact plug through the first insulating layer on substrate; forming a magnetic tunnel junction pattern contacting the first contact plug on the first insulating layer; forming a spacer having a metal oxide layer on a sidewall of the magnetic tunnel junction pattern; forming a second insulating layer over the magnetic tunnel junction pattern and the spacer; and forming a second contact plug through the first and second insulating layers; forming a third insulating layer on the second insulating layer; forming a first hole exposing the magnetic tunnel junction pattern and a second hole exposing the second contact plug by etching the first and second insulating layer; and forming a first and second electric wires by burying a conducting material in the first and second hole.

In accordance with an embodiment of the present invention, a semiconductor device, comprising a magnetic tunnel junction pattern; and a spacer having a metal oxide layer formed on a sidewall of the magnetic tunnel junction pattern.

### BRIEF DESCRIPTION OF THE DRAWINGS

FIGS. 1a to 1h are sectional views illustrating a method for fabricating a semiconductor device in accordance with an embodiment of the present invention.

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

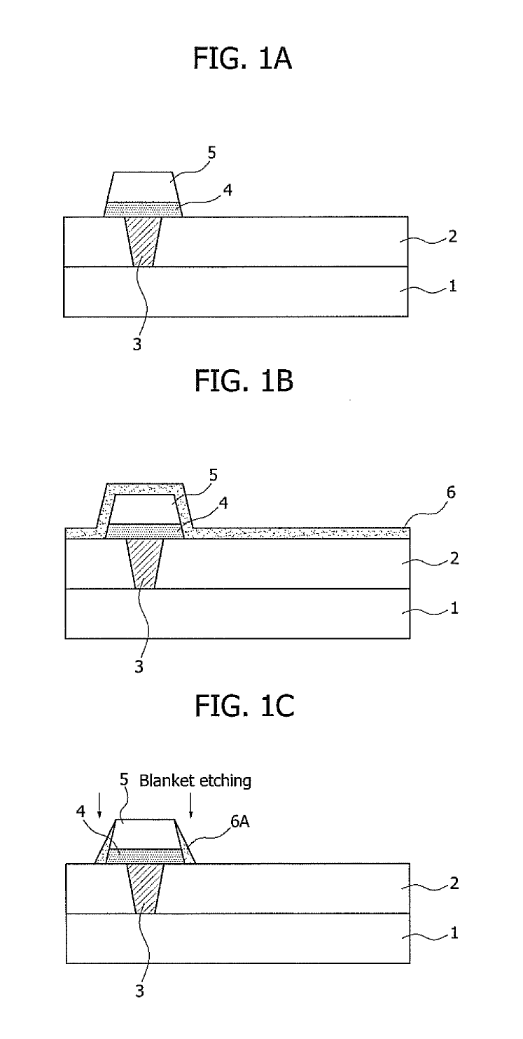

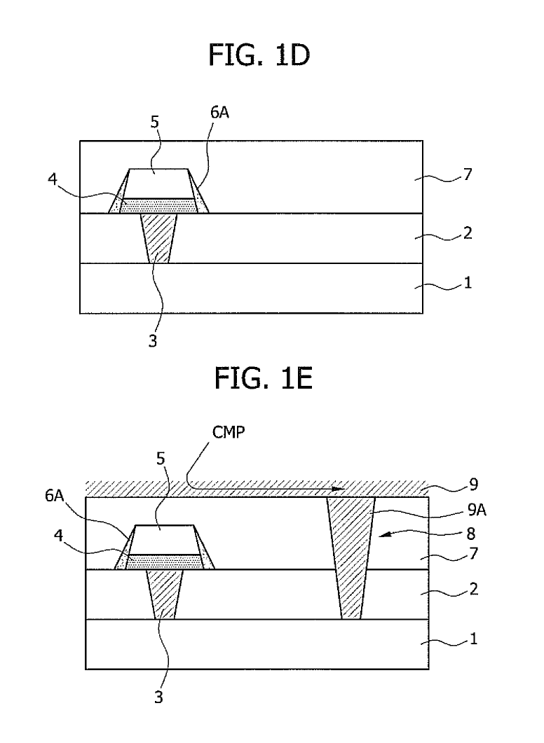

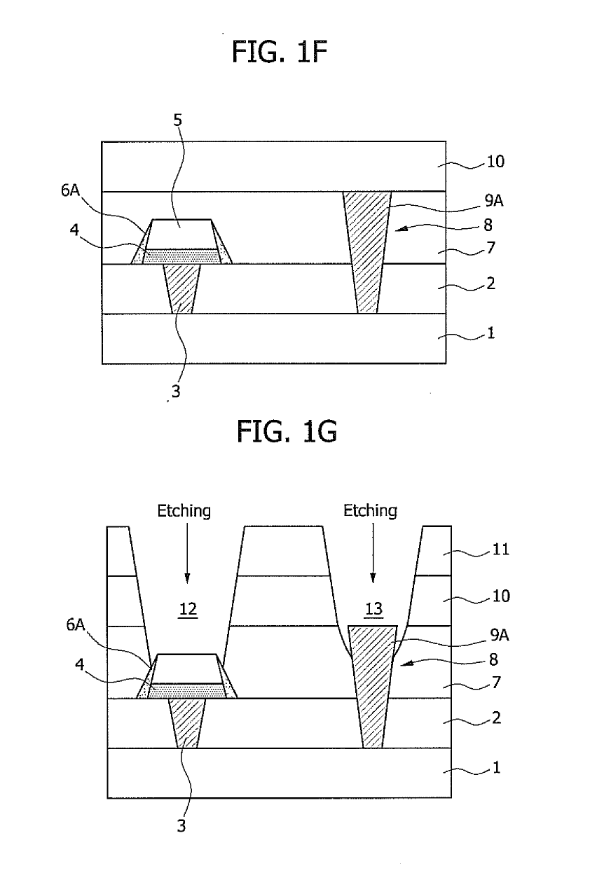

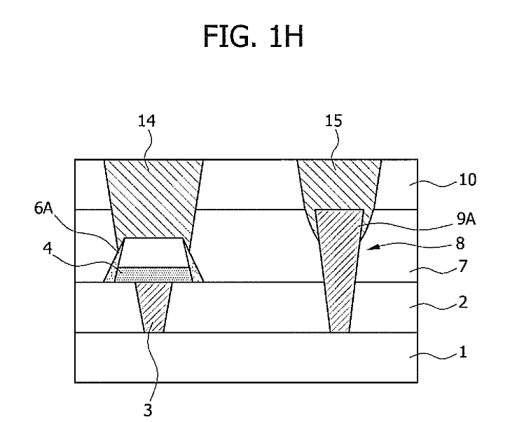

FIGS. 1a to 1h are sectional views illustrating a method for fabricating a semiconductor device in accordance with an embodiment of the present invention.

As illustrated in FIG. 1A, a first interlayer insulating layer 2 is formed on a substrate having a bottom layer 1.

The first interlayer insulating layer 2 is used as an insulating layer. The first interlayer insulating layer 2 is formed of one or more from the group consisting of a boro silicate glass (BSG) layer, a boro phospho silicate glass (BPSG) layer, a phosphor silicate glass (PSG) layer, a tetra ethyl ortho silicate (TEOS) layer, a high density plasma (HDP) oxide layer, and a spin on glass (SOG) layer.

Subsequently, a first contact plug 3 is formed to pass through the first interlayer insulating layer 2.

The bottom layer 1 includes the first contact plug 3 and a transistor having a junction area connected to the contact plug 3 to select a magnetic tunnel junction. The first contact plug 3 is formed of a metal layer.

Subsequently, a magnetic tunnel junction 4 and a hard mask layer 5 are formed. Here, the magnetic tunnel junction 4 comes in contact with the contact plug 3 because the magnetic tunnel junction 4 is formed over the contract plug 3.

The magnetic tunnel junction 4 includes a first magnetic layer, a tunnel insulating layer, and a second magnetic layer.

The first magnetic layer includes a diamagnetic layer referred to as a pinning layer and a ferromagnetic layer referred to as a pinned layer. The pinning layer functions to fix the magnetization direction of the pinned layer. To this end, the pinning layer is formed of a thin film made of one or more selected from the group consisting of IrMn, PtMn, MnO, MnS, MnTe, MnF₂, FeF₂, FeCl₂, FeO, CoCl₂, CoO, NiCl₂, and NiO. The magnetization direction of the pinned layer is fixed by the pinning layer. To this end, the pinned layer is formed of a thin film made of one or more selected from the group consisting of Fe, Co, Ni, Gd, Dy, NiFe, CoFe, MnAs, MnBi, MnSb, CrO₂, MnOFe₂O₃, FeOFe₂O₃, NiOFe₂O₃, CuOFe₂O₃, EuO, and Y₃Fe₅O₁₂.

The tunnel insulating layer may be a MgO layer. Alternatively, the tunnel insulating layer may be formed of a Group-IV semiconductor layer or may be formed by adding a Group-III or Group V element such as B, P, or As to the semiconductor layer to control the electric conductivity of the tunnel insulating layer.

The magnetization direction of the second magnetic layer changes depending on a direction of current supplied thereto. To this end, the second magnetic layer is formed of a thin film made of one or more selected from the group consisting of Fe, Co, Ni, Gd, Dy, NiFe, CoFe, MnAs, MnBi, MnSb, CrO₂, MnOFe₂O₃, FeOFe₂O₃, NiOFe₂O₃, CuOFe₂O₃, EuO, and Y₃Fe₅O₁₂.

The hard mask layer 5 protects the magnetic tunnel junction 4 and serves as a top electrode. The hard mask layer 5 is also used as an etch barrier for patterning the magnetic tunnel junction 4. To this end, the hard mask layer 5 is formed of tungsten (W).

Hereafter, for illustration purposes, the magnetic tunnel junction 4 and the hard mask layer 5 are commonly referred to as a magnetic tunnel junction pattern.

As illustrated in FIG. 1B, a metal oxide layer 6 is formed on the substrate having the magnetic tunnel junction pattern formed on the substrate.

The metal oxide layer 6 may be a thin film made of one or more selected from the group consisting of Al₂O₃ and ZrO₂, and the thickness of the metal oxide layer 6 may be 10 to 500 Å.

As illustrated in FIG. 1C, a spacer 6A is formed by performing a blanket etching process on the metal oxide layer 6. The blanket etching process may be an etch back process.

The blanket etching process is performed using a mixture gas of Cl₂ and BCl₃. The blanket etching process may be performed by adding one or more selected from the group consisting of O₂, N₂, and Ar to the mixture gas. The mixture ratio of the Cl₂ to the BCl₃ may be 9(Cl₂):1(BCl₃). The O₂, N₂, or Ar added to the mixture gas may be 0.01 to 50% of the total amount of the mixture gas. The spacer 6A protects a sidewall of the magnetic tunnel junction pattern.

In addition, the spacer 6A may have a structure where an insulating layer and a metal oxide layer are laminated, and the metal oxide layer is disposed at the outside surface of the spacer 6A.

As illustrated in FIG. 1D, a second interlayer insulating layer 7 is formed on the substrate having the spacer 6A formed thereon. In this embodiment, the second interlayer insulating layer 7 is formed to completely cover the top of the hard mask layer 5.

The second interlayer insulating layer 7 is used as an insulating layer. The second interlayer insulating layer 7 is formed of one or more selected from the group consisting of a BSG layer, BPSG layer, a PSG layer, a TEOS layer, an HDP oxide layer, and an SOG layer.

As illustrated in FIG. 1E, a first contact hole 8 is formed by etching a portion of the second interlayer insulating layer 7 and a portion of the first interlayer insulating layer 2, and a metal layer 9 is then buried in the first contact hole 8.

In this embodiment, a thin film, such as an etch stop layer, which has an etch selectivity different from the first and second interlayer insulating layers 2 and 7, is not interposed between the first and second interlayer insulating layers 2 and 7. Hence, the sidewall of the first contact hole 8 is linearly formed.

Subsequently, a second contact plug 9A is formed in the first contact hole 8 by performing a planarization process on the metal layer 9. Since the sidewall of the first contact hole 8 is linearly formed, the second contact plug 9A is completely buried in the first contact hole 8, and thus a burying failure does not occur. The planarization process may be a chemical mechanical polishing (CMP) process.

As illustrated in FIG. 1F, a third interlayer insulating layer 10 is formed on the substrate having the second contact plug 9A formed thereon.

The third interlayer insulating layer 10 is used as an insulating layer. The third interlayer insulating layer 10 is formed of one or more selected from the group consisting of a BSG layer, BPSG layer, a PSG layer, a TEOS layer, an HDP oxide layer, and an SOG layer.

As illustrated in FIG. 1G, a damascene process is performed. More specifically, a first mask pattern 11 is formed on the third interlayer insulating layer 10, and the third and second interlayer insulating layers 10 and 7 are etched using the first mask pattern 11 as an etch barrier. Accordingly, first and second damascene patterns 12 and 13 are formed.

The first mask pattern 11 is formed into a structure where an amorphous carbon layer, a SiON layer, an anti-reflection layer, and a photoresist pattern are laminated.

The etching process of the second and third interlayer insulating layers 7 and 10 is performed using one or more from the etch gas group consisting of CF₄, CHF₃, CH₃F, and C₄F₆. The etching process may be performed by adding O₂ or Ar to the etch gas.

The depth of the first damascene pattern 12 is formed to expose only the hard mask layer 5. However, since exactly aligning an etch target may be difficult, the depth of the first damascene pattern 12 may expose the hard mask layer 5 and the magnetic tunnel junction 4. Therefore, the magnetic tunnel junction 4 may be exposed. For this reason, the magnetic tunnel junction 4 may be damaged. However, the spacer 6A is formed on the sidewall of the magnetic tunnel junction 4. Hence, although the depth of the first damascene pattern 12 is formed to expose the magnetic tunnel junction 4, the magnetic tunnel junction 4 is not damaged. Particularly, since the spacer 6A is formed with the metal oxide layer, which has an excellent etch selectivity with the etch gas for etching the second and third interlayer insulating layers 7 and 10, the spacer 6A can stably protect the magnetic tunnel junction 4 during the process of forming the first damascene pattern 12.

The depth of the second damascene pattern 13 is formed to expose an upper portion of the second contact plug 9A.

Subsequently, the first mask pattern 11 is removed.

The first mask pattern 11 is removed using a stripping process, and a cleaning process is subsequently performed.

As illustrated in FIG. 1h, first and second wires 14 and 15 are formed by burying metal layers in the first and second damascene patterns 12 and 13, respectively. The first and second wires 14 and 15 are formed of a metal layer, particularly, tungsten (W) or copper (Cu).

The first wire 14 serves as a wire for supplying current to the magnetic tunnel junction 4, and the second wire 15 serves as a wire for supplying current to the junction area of the transistor connected to the second contact plug 9A.

As described above, in the resistance-variation random access memory in accordance with the embodiment of the present invention, the spacer 6A is disposed on the sidewalls of the magnetic tunnel junction pattern to prevent the magnetic tunnel junction 4 from being damaged when forming the first damascene pattern 12. Particularly, if the spacer 6A is formed with a metal oxide layer and the interlayer insulating layers 2 and 7 are etched using one or more gas selected from the group consisting of CF₄, CHF₃, CH₃F, and C₄F₆, the spacer 6A is not etched. Thus, the magnetic tunnel junction 4 may not be damaged.

While the present invention has been described with respect to the specific embodiments, it will be apparent to those skilled in the art that various changes and modifications may be made without departing from the spirit and scope of the invention as defined in the following claims. Although it has been illustrated in that the magnetic tunnel junction is a magnetic tunnel junction of the STTRAM, the present invention is not limited thereto. More specifically, the magnetic tunnel junction is applicable to all processes of connecting a general electrode and a metal wire to each other through a damascene process. For example, the magnetic tunnel junction may be a magnetic tunnel junction of the ReRAM.

What is claimed is:

1. A method for fabricating a semiconductor device, the method comprising:
forming a magnetic tunnel junction pattern on a substrate;
forming a spacer having a metal oxide layer on a sidewall of the magnetic tunnel junction pattern;
forming a first interlayer insulating layer on the substrate having the spacer and the magnetic tunnel junction pattern formed thereon;
forming a first damascene pattern by etching the first interlayer insulating layer so that a top portion of the magnetic tunnel junction pattern is exposed; and
forming a first wire buried in the first damascene pattern.

2. The method of claim 1, wherein the metal oxide layer is formed of at least one of Al₂O₃ and ZrO₂.

3. The method of claim 2, wherein the first interlayer insulating layer is formed of an oxide-based layer.

4. The method of claim 3, wherein the forming of the first damascene pattern is performed using at least one etch gas of CF₄, CHF₃, CH₃F, and C₄F₆, and is performed by adding O₂ or Ar to the etch gas.

5. The method of claim 1, wherein the magnetic tunnel junction pattern comprises a magnetic tunnel junction and a hard mask layer formed on the magnetic tunnel junction.

6. The method of claim 1, further comprising forming a contact plug passing through the first interlayer insulating layer after forming the first interlayer insulating layer.

7. The method of claim 1, wherein the forming of the spacer pattern comprises forming a metal oxide layer on the substrate having the magnetic tunnel junction pattern formed on the substrate, and performing a blanket etch process on the metal oxide layer.

8. A method for fabricating a semiconductor device, the method comprising:
forming a first insulating layer on a substrate;
forming a first contact plug through the first insulating layer on substrate;
forming a magnetic tunnel junction pattern contacting the first contact plug on the first insulating layer;
forming a spacer having a metal oxide layer on a sidewall of the magnetic tunnel junction pattern;
forming a second insulating layer over the magnetic tunnel junction pattern and the spacer; and
forming a second contact plug through the first and second insulating layers;
forming a third insulating layer on the second insulating layer;
forming a first hole exposing the magnetic tunnel junction pattern and a second hole exposing the second contact plug by etching the first and second insulating layer; and
forming a first and second electric wires by burying a conducting material in the first and second hole.

9. The method of claim 8, wherein the metal oxide layer is formed of at least one of Al₂O₃ and ZrO₂.

10. The method of claim 8, wherein the first interlayer insulating layer is formed of an oxide-based layer.

11. The method of claim 8, wherein the forming of the first and second holes is performed using at least one etch gas of CF₄, CHF₃, CH₃F, and C₄F₆, and is performed by adding O₂ or Ar to the etch gas.

12. A semiconductor device, comprising:
a magnetic tunnel junction pattern; and
a spacer having a metal oxide layer formed on a sidewall of the magnetic tunnel junction pattern.

13. The semiconductor device of the claim 12, further comprising:
a first contact plug formed in a first insulating layer and arranged below the magnetic tunnel junction pattern;
a second insulating layer covering the magnetic tunnel junction pattern;
a third insulating layer formed on the second insulating layer;
a first metal line connected to the magnetic tunnel junction pattern and formed in an etched portion of the second and third insulating layers;
a second contact plug formed in a first and second insulating layers; and
a second metal line connected to the second contact plug pattern and formed in an etched portion of the third insulating layers.
